(19) United States
(12) Patent Application Publication
(10) Pub. No.: US 2009/0244837 A1
(43) Pub. Date: Oct. 1, 2009

(54) Heat-dissipating module

(75) Inventors: Cheng-Chin Chan, Taipei City (TW); Chun-Huang Chou, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., Taipei City (TW)

(21) Appl. No.: 12/213,248

(22) Filed: Jun. 17, 2008

(30) Foreign Application Priority Data
Apr. 1, 2008 (TW) 97205586

(51) Int. Cl. H05K 7/20; F28F 7/00

(52) U.S. Cl. 361/689; 165/80.2

(57) ABSTRACT

A heat-dissipating module includes a heat-dissipating member and at least one heat pipe. The heat-dissipating member includes a pillared convexity and an annular groove formed on and surrounding the heat-dissipating member. The at least one heat pipe passes through the annular groove, partially surrounding the convexity and stopped against the convexity.

### BACKGROUND OF THE INVENTION

1. Field of the Invention

The present invention relates generally to heat-dissipating modules, and more particularly, to structure of a heat-dissipating module.

2. Description of the Related Art

Referring to FIG. 9, a conventional heat-dissipating module 1 includes a substrate 2, an upper plate 3 mounted to a top side of the substrate 2, a plurality of heat pipes 4 passing through the substrate 2 and the upper plate 3, a plurality of fins 5 mounted to the heat pipes 4, and a fan 6. A bottom side of the substrate 2 is closely in contact with a chip (not shown). In this way, the heat generated by the chip is transferred through the substrate 2 to the heat pipes 41 and through the fins 5 and then blew outside by the fan 6 for quick thermal dissipation.

As we know, the heat is transferred by the contact between the substrate 2, the upper plate 2, and the heat pipes 4. Basically, the larger the contact area between them is, the more efficient the thermal dissipation will be. However, the contact area between the substrate 2, the upper plate 3, and the heat pipes 4 of the aforementioned conventional heat-dissipating module 1 is limited to provide efficient thermal dissipation. In other words, the conventional heat-dissipating module 1 is defective in small contact area and inefficient thermal dissipation.

### SUMMARY OF THE INVENTION

The primary objective of the present invention is to provide a heat-dissipating module, which provides larger contact area to have preferable heat-dissipating efficiency.

The foregoing objective of the present invention is attained by the heat-dissipating module composed of a heat-dissipating member and at least one heat pipe. The heat-dissipating member includes a pillared convexity and an annular groove formed on and surrounding the heat-dissipating member. The at least one heat pipe passes through the annular groove, partially surrounding the convexity and stopped against the convexity.

In light of the above structure, the contact area between the heat-dissipating member and the heat pipe is greatly enhanced to facilitate transferring heat from the heat-dissipating member to the heat pipe. Therefore, the present invention has more efficient thermal dissipation than the prior art did.

### BRIEF DESCRIPTION OF THE DRAWINGS

FIG. 1 is a perspective view of a first preferred embodiment of the present invention.

FIG. 2 is a front view of the first preferred embodiment of the present invention.

FIG. 3 is a top view of the first preferred embodiment of the present invention.

FIG. 4 is a perspective view of a second preferred embodiment of the present invention.

FIG. 5 is a front view of the second preferred embodiment of the present invention.

FIG. 6 is a perspective view of a third preferred embodiment of the present invention.

FIG. 7 is a front view of the third preferred embodiment of the present invention.

FIG. 8 is a top view of the third preferred embodiment of the present invention.

FIG. 9 is a side view of the prior art.

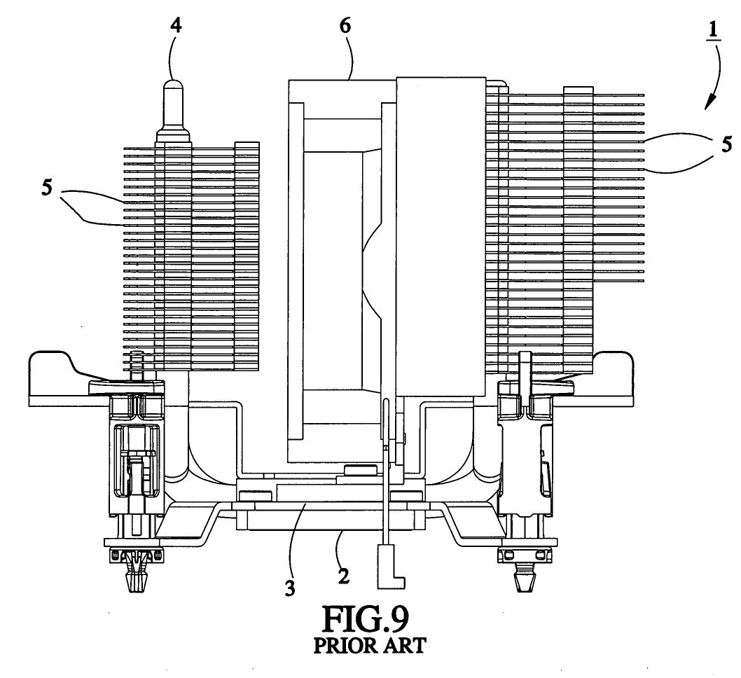

### DETAILED DESCRIPTION OF PREFERRED EMBODIMENTS

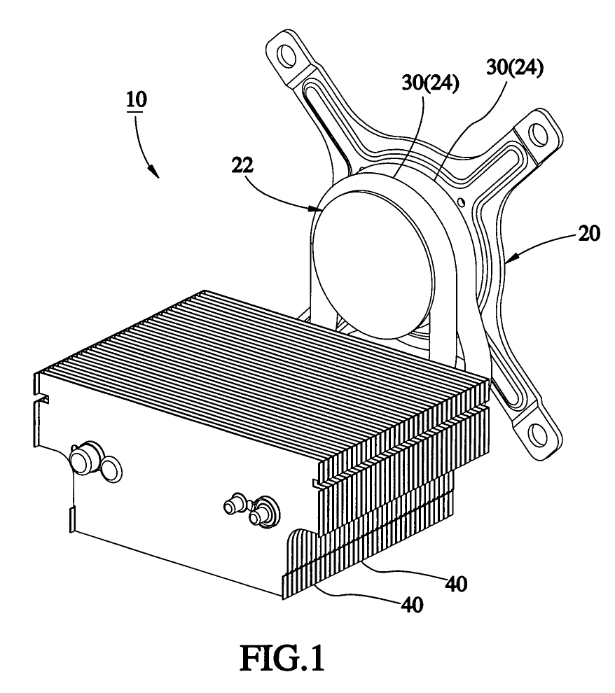

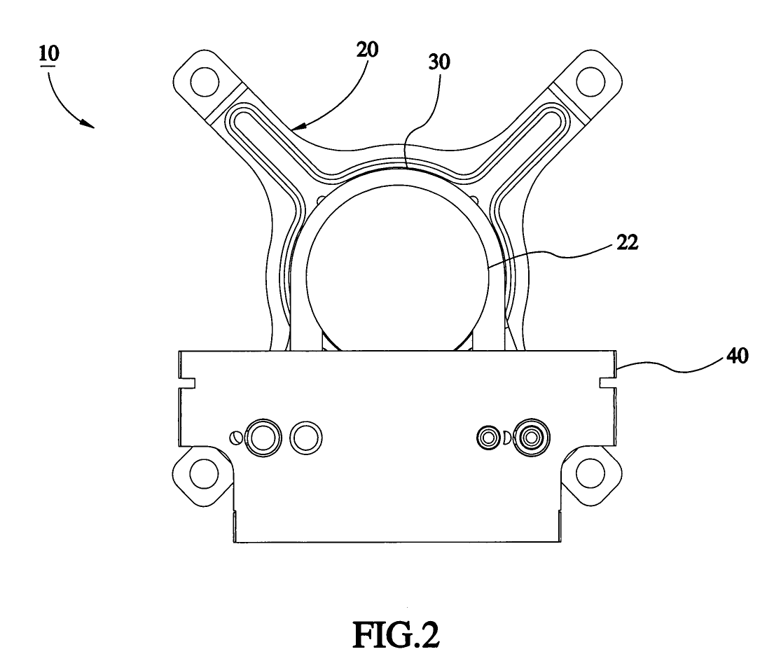

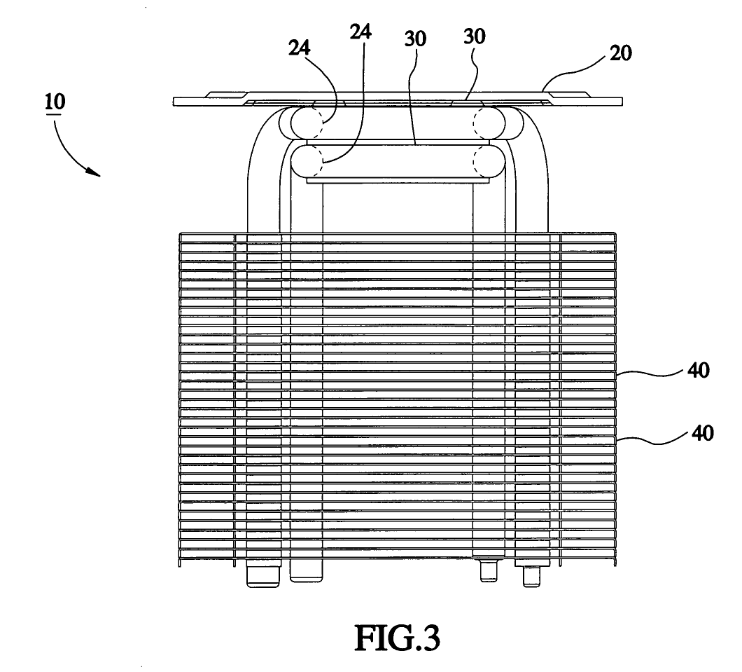

Referring to FIGS. 1-3, a heat-dissipating module 10 in accordance with a first preferred embodiment of the present invention is composed of a heat-dissipating member 20 and two heat pipes 30.

The heat-dissipating member 20 at its bottom side is in contact with a top side of a chip (not shown) for transferring outside heat generated by the chip. The heat-dissipating member 20 includes a pillared convexity 22 and two annular grooves 24 formed on the convexity 22. The convexity 22 includes a column-shaped middle part. The two annular grooves 24 parallel surround the middle part of the convexity 22.

The two heat pipes 30 are mounted to the convexity 22, passing through the two annular grooves 24 respectively. A midsection of each of the heat pipes 30 partially surrounds the convexity 22. Each of the heat pipes 30 is curved around the convexity 22 for an angle larger than 180 degrees and is rotatable on the annular groove 24 with respect to the convexity 22. A plurality of fins 40 are mounted in parallel to external distal ends of the heat pipes 30 for outward dissipation of the heat of the heat pipes 30. The midsection of each of the heat pipes 30 is stopped against the convexity 22 for conducting the heat of the pillared convexity 22 to the fins 40.

In this way, the heat-dissipating module 10 can enlarge the contact area between the heat pipes 30 and the convexity 22 of the heat-dissipating member 20 to speed up the transmission of the heat from the heat-dissipating member 20 to the heat pipes 30. Compared with the prior art, the present invention indeed has higher heat-dissipating efficiency. In addition, the heat pipes 30 are adjustable in orientation subject to the user's requirement to have operational convenience.

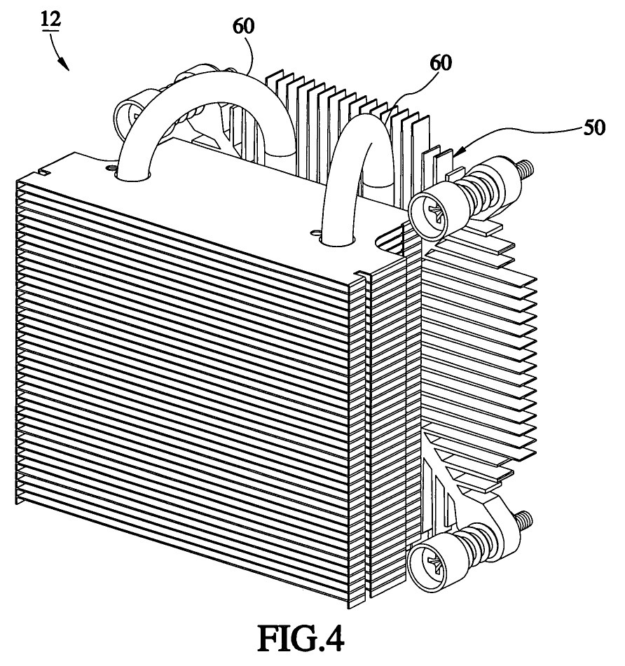

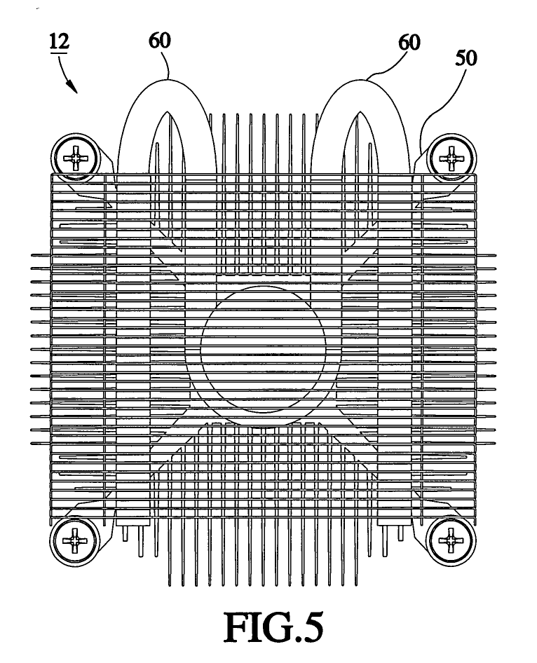

Referring to FIGS. 4 and 5, a heat-dissipating module 12 in accordance with a second preferred embodiment of the present invention is similar to the first embodiment, having a heat-dissipating member 50 and a heat pipe 60. The heat-dissipating module 12 of the second embodiment is different from that of the first embodiment only by the number of the heat pipe 60 and how the distal end of the heat pipe 60 is curved. In light of this, the heat-dissipating module 12 of the second embodiment can attain the same effect as that of the first embodiment does.

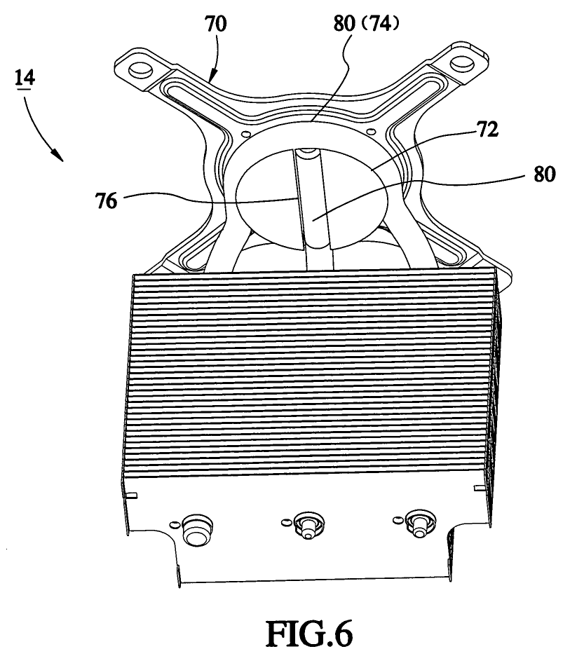

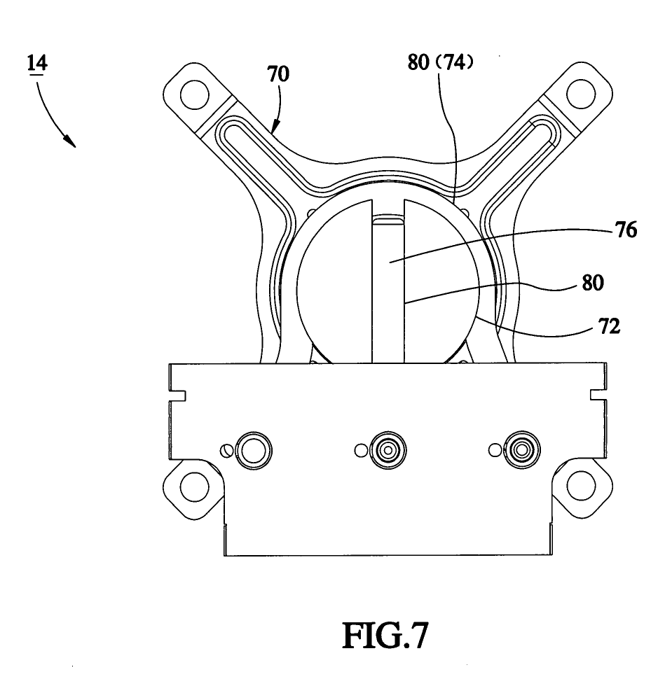

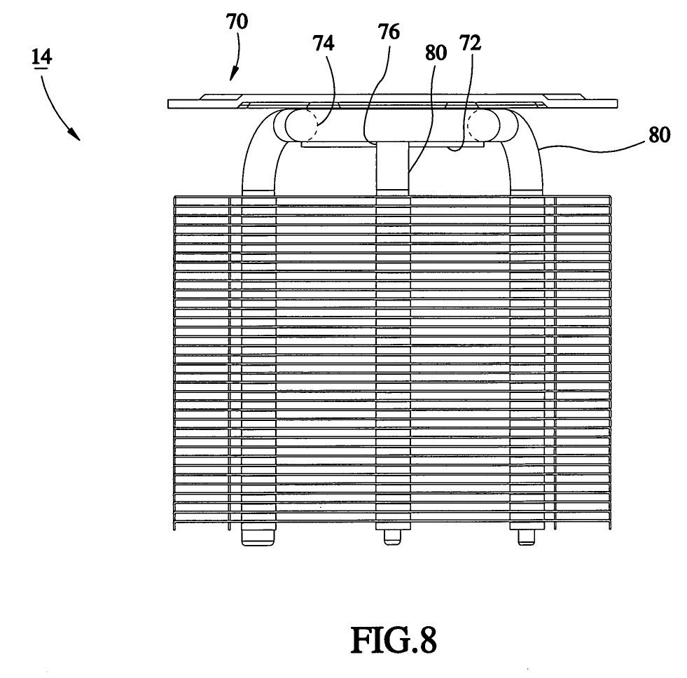

Referring to FIGS. 6-8, a heat-dissipating module 14 in accordance with a third preferred embodiment of the present invention is similar to the first embodiment, likewise having a heat-dissipating member 70 and two heat pipes 80. The two embodiments are different from each other in that the convexity 72 of the heat-dissipating member 70 includes an annular groove 74 and an elongated straight groove 76. The elongated straight groove 76 is provided for one of the heat pipes 80 to pass through for enlarging the contact area between the heat pipe 80 and the convexity 72, such that the heat-dissipating efficiency can be heightened. In addition, the heat pipes 80 are not rotatable with respect to the convexity 72. In light of this, the heat-dissipating module 14 of the third embodiment can attain the same effect as that of the first embodiment does.

Although the present invention has been described with respect to specific preferred embodiments thereof, it is no way limited to the details of the illustrated structures but changes and modifications may be made within the scope of the appended claims.

What is claimed is:

1. A heat-dissipating module comprising:
a heat-dissipating member having a pillared convexity and an annular groove formed on said convexity, said annular grove surrounding said convexity; and
at least one heat pipe partially surrounding said convexity and passing through said annular groove.

2. The heat-dissipating module as defined in claim 1, wherein said at least one heat pipe is rotatable on said annular groove with respect to said convexity.

3. The heat-dissipating module as defined in claim 1, wherein said at least one heat pipe is curved for an angle larger than 180 degrees.

4. The heat-dissipating module as defined in claim 1, wherein said at least one heat pipe is externally connected with a plurality of fins arranged in parallel.

5. The heat-dissipating module as defined in claim 1, wherein said convexity further comprises a groove for said at least one heat pipe to pass through.

6. The heat-dissipating module as defined in claim 1, wherein said convexity comprises a column-shaped middle part.
